(19) United States
(12) Patent Application Publication
(10) Pub. No.: US 2015/0046103 A1
(43) Pub. Date: Feb. 12, 2015

(54) OPERATIONAL STATE ESTIMATING APPARATUS FOR ELECTRICAL DEVICE, OPERATIONAL STATE ESTIMATING METHOD FOR ELECTRICAL DEVICE, PROGRAM, FEATURE VECTOR REGISTERING APPARATUS FOR ELECTRICAL DEVICE, FEATURE VECTOR REGISTERING METHOD FOR ELECTRICAL DEVICE, SERVER DEVICE, AND OPERATIONAL STATE ESTIMATING SYSTEM FOR ELECTRICAL DEVICE

(71) Applicant: SONY CORPORATION, Tokyo (JP)

(72) Inventors: Mototsugu Abe, Kanagawa (JP); Takashi Shibuya, Tokyo (JP); Masayuki Nishiguchi, Kanagawa (JP)

(73) Assignee: SONY CORPORATION, Tokyo (JP)

(21) Appl. No.: 14/385,531

(22) PCT Filed: Feb. 18, 2013
(86) PCT No.: PCT/JP13/53854

§ 371 Date: Sep. 16, 2014

(30) Foreign Application Priority Data
Apr. 18, 2012 (JP) 2012-094457

(51) Int. Cl. G01R 21/06

(52) U.S. Cl. CPC G01R 21/06
USPC 702/60

(57) ABSTRACT

Estimating operational states of a plurality of electrical devices connected to an electrical power line, that is, an electricity usage condition is appropriately carried out.

Current and voltage are calculated as time-series from the electrical power line to which the plurality of electrical devices is connected. Signal components of power frequency and harmonics thereof are extracted from the time-series of the current and the voltage. Admittance vector time-series are calculated from the signal components. The admittance vector time-series are compared with combinations of feature vectors of the plurality of electrical devices connected to the electrical power line, to obtain an estimated result of the operational states of the plurality of electrical devices.

### TECHNICAL FIELD

The present technology relates to an operational state estimating apparatus for an electrical device, an operational state estimating method for the electrical device, a program, a feature vector registering apparatus for the electrical device, a feature vector registering method for the electrical device, a server device, and an operational state estimating system for the electrical device.

### BACKGROUND ART

Because of the spread of global environmental problems and the like, demands have been increasing for grasping, in detail, electricity usage conditions of electrical devices owned by each household and each individual. For example, by visualizing the electricity usage condition of each device in a household at every moment, electricity charges can be saved by turning off unnecessary electrical devices. Further, electricity can be effectively saved when power supply is strained.

In the past, an electricity usage amount has been measured by an electric energy meter in a unit for imposing electricity charges such as a household unit (see, for example, Patent Document 1). In some quarters, the electricity usage amount has been measured in a smaller unit by disposing a dedicated tool near each electrical device such as an outlet.

### CITATION LIST

### Patent Document

Patent Document 1: JP 2002-354560 A

### SUMMARY OF THE INVENTION

### Problems to be Solved by the Invention

A total amount of electricity usage is sufficient for calculating electricity charges. However, it is less useful for effectively saving electricity according to time and circumstances. On the other hand, disposing a dedicated tool on each outlet requires labor and costs. Therefore, it has not been prevailed.

An object of the present technology is to appropriately estimate operational states of a plurality of electrical devices connected to an electrical power line, that is, an electricity usage condition.

### Solutions to Problems

A concept of the present technology is an operational state estimating apparatus for an electrical device including:

a current-voltage measuring unit configured to measure current and voltage as time-series from an electrical power line to which a plurality of electrical devices is connected;

a filtering unit configured to filter signal components of power frequency and harmonics thereof from the time-series of the measured current and voltage;

an admittance calculating unit configured to calculate admittance vector time-series from the filtered signal components;

a feature vector retaining unit configured to retain feature vectors of the plurality of electrical devices;

a combination calculating unit configured to calculate combination patterns of the retained feature vectors of the plurality of electrical devices; and

a comparing unit configured to compare the combined feature vectors and the calculated admittance vector time-series to obtain an estimated result of the operational states of the plurality of electrical devices.

In the present technology, the current and voltage are measured as the time-series by the current-voltage measuring unit from the electrical power line to which the plurality of electrical devices is connected. The signal components of the power frequency and the harmonics thereof are filtered by the filtering unit from the time-series of those measured current and voltage. Further, the admittance vector time-series are calculated by the admittance calculating unit from the signal components filtered by the filtering unit. In such a case, the admittance vector includes admittances of both the power frequency and the harmonics thereof as elements.

The feature vectors of the plurality of electrical devices are retained in the feature vector retaining unit. For example, a feature vector of a predetermined electrical device includes one or a plurality of feature vectors extracted, by vector quantization, from admittance vector time-series when the predetermined electrical device is in an operational state. The combination patterns of the retained feature vectors of the plurality of electrical devices are calculated by the combination calculating unit.

For example, the combination calculating unit may be configured so as to calculate all the combination patterns of the retained feature vectors. By calculating all the combination patterns in this manner, the estimated result of the operational states of the plurality of electrical devices can be obtained with high accuracy.

Further, for example, the combination calculating unit may be configured so as to calculate combination patters, in which the operational states of the devices have been stochastically changed, from an estimated result of the latest device operational state based on combination patterns in which the operational states of devices within a predetermined quantity have been changed and/or based on a predetermined probability distribution. In such a case, the predetermined probability distribution may be one calculated from past histories of the operational states of the plurality of electrical devices. Further, in such a case, the predetermined probability distribution may be one according to time that is selected from a plurality of probability distributions calculated according to day and time. In such a case, the quantity of the combination patterns as well as a processing load can be reduced.

The combined feature vectors are compared with the calculated admittance vector time-series by the comparing unit to obtain the estimated result of the operational states of the plurality of electrical devices. For example, the comparing unit calculates inter-vector distances between the combined feature vectors and the calculated admittance vector time-series. A combination having the shortest distance is set as the estimated result of the operational states of the plurality of electrical devices.

As mentioned above, in the present technology, the admittance vector time-series obtained based on the current and voltage measured by the electrical power line are compared with the combinations of the feature vectors of the plurality of electrical devices connected to the electrical power line to obtain the estimated result of the operational states of the plurality of electrical devices. Herein, it is possible to appropriately estimate the operational states of the plurality of electrical devices, that is, an electricity usage condition.

Another concept of the present technology is a feature vector registering apparatus for an electrical device, including:

a current-voltage measuring unit configured to measure current and voltage as time-series from an electrical power line to which a plurality of electrical devices is connected;

a filtering unit configured to filter signal components of power frequency and harmonics thereof from the time-series of the measured current and voltage;

an admittance calculating unit configured to calculate admittance vector time-series from the filtered signal components;

a feature vector extracting unit configured to extract feature vectors of each of the plurality of electrical devices from the calculated admittance vector time-series; and

a feature vector registering unit configured to register, on a database, the extracted feature vectors of the plurality of electrical devices.

In the present technology, the current and voltage are measured as the time-series by the current-voltage measuring unit from the electrical power line to which the plurality of electrical devices is connected. The signal components of the power frequency and the harmonics thereof are filtered by the filtering unit from the time-series of those measured current and voltage. Then, the admittance vector time-series are calculated from the filtered signal components by the admittance calculating unit. In such a case, the admittance vector includes admittances of both the power frequency and the harmonics thereof as elements.

The feature vectors of each of the plurality of electrical devices are extracted by the feature vector extracting unit from the calculated admittance vector time-series. Further, the extracted feature vectors of the plurality of electrical devices are registered on the database by the feature vector registering unit.

For example, when it is possible to drive only a predetermined electrical device, the feature vector extracting unit may be configured to extract one or a plurality of feature vectors, as a feature vector of the predetermined electrical device, from the admittance vector time-series by vector quantization.

Further, for example, when it is difficult to drive only the predetermined electrical device, the feature vector extracting unit may be configured to estimate admittance vector time-series of the predetermined electrical device from the calculated admittance vector time-series, and to extract one or a plurality of feature vectors, as the feature vector of the predetermined electrical device, from the admittance vector time-series by the vector quantization.

In such a case, for example, the feature vector extracting unit may be configured to estimate admittance vector time-series of an electrical device other than the predetermined electrical device from the calculated admittance vector time-series in a case where the predetermined electrical device is not in an operational state. Then, the feature vector extracting unit may be configured to extract the admittance vector time-series of the predetermined electrical device by removing an estimate value of the admittance vector time-series of the electrical device other than the predetermined electrical device from the calculated admittance vector time-series in a case where the predetermined electrical device is in the operational state.

In such a case, for example, the feature vector extracting unit may be configured to estimate the admittance vector time-series of the electrical device other than the predetermined electrical device by according and compositing phases of the calculated admittance vector time-series in time periods before and after driving the predetermined electrical device so that a correlation value of the admittance vector time-series becomes the highest.

As mentioned above, in the present technology, the feature vectors of each of the plurality of electrical devices connected to the electrical power line can be favorably extracted and registered on the database from the admittance vector time-series obtained based on the current and voltage measured by the electrical power line.

Another concept of the present technology is an operational state estimating apparatus for an electrical device including:

a current-voltage measuring unit configured to measure current and voltage as time-series from an electrical power line to which a plurality of electrical devices is connected;

a filtering unit configured to filter signal components of power frequency and harmonics thereof from the time-series of the measured current and voltage;

an admittance calculating unit configured to calculate admittance vector time-series from the filtered signal components;

an admittance transmitting unit configured to transmit the calculated admittance vector time-series to a server device; and

an estimated result receiving unit configured to receive an estimated result of the operational states of the plurality of electrical devices from the server device.

In the present technology, the current and voltage are measured as the time-series by the current-voltage measuring unit from the electrical power line to which the plurality of electrical devices is connected. The signal components of the power frequency and the harmonics thereof are filtered by the filtering unit from the time-series of those measured current and voltage. Further, the admittance vector time-series are calculated by the admittance calculating unit from the signal components filtered by the filtering unit. In such a case, the admittance vector includes admittances of both the power frequency and the harmonics thereof as elements.

The calculated admittance vector time-series are transmitted to the server device by the admittance transmitting unit. The estimated result of the operational states of the plurality of electrical devices is received by the estimated result receiving unit from the server device.

As mentioned above, the present technology does not carry out a process of estimating the operational states of the plurality of electrical devices connected to the electrical power line from the admittance vector time-series. Instead, the server device carries out the process. Accordingly, it is possible to reduce a processing load and to obtain the estimated result with high accuracy due to a high-performance process of the server device.

Further, another concept of the present technology is a server device, including:

an admittance receiving unit configured to receive admittance vector time-series transmitted from a terminal device;

a feature vector retaining unit configured to retain feature vectors of a plurality of electrical devices;

a combination calculating unit configured to calculate combination patterns of the retained feature vectors of the plurality of electrical devices;

a comparing unit configured to compare the combined feature vectors and the received admittance vector time-series to obtain an estimated result of the operational states of the plurality of electrical devices; and

an estimated result transmitting unit configured to transmit the obtained estimated result of the operational states of the plurality of electrical devices to the terminal device.

In the present technology, the admittance vector time-series transmitted from the terminal device are received by the admittance receiving unit. The combination patterns of the feature vectors of the plurality of electrical devices retained by an admittance vector retaining unit are calculated by the combination calculating unit. Note that the feature vectors of the plurality of electrical devices retained by the feature vector retaining unit may be, for example, extracted in advance by the server device itself from the admittance vector time-series transmitted from the terminal device. Alternatively, the feature vectors may be received in advance from the terminal device.

The combined feature vectors and the received admittance vector time-series are compared by the comparing unit to obtain the estimated result of the operational states of the plurality of electrical devices. Then, the obtained estimated result of the operational states of the plurality of electrical devices is transmitted to the terminal device by the estimated result transmitting unit.

As mentioned above, the present technology carries out, instead of the terminal device, a process of estimating the operational states of the plurality of electrical devices connected to the electrical power line from the admittance vector time-series. Accordingly, it is possible to reduce the processing load of the terminal device and to provide the estimated result to the terminal device with high accuracy due to the high-performance process.

Note that in the present technology, for example, the terminal device may further include a request-to-send receiving unit configured to receive a request-to-send of the estimated result transmitted from another terminal device different the terminal devices. Further, the estimated result transmitting unit may transmit the obtained estimated result of the operational states of the plurality of electrical devices to the other terminal device based on the received request-to-send. As a result, it is possible for a user to confirm the estimated result of the operational states of the plurality of electrical devices by other terminals (portable terminal) different from a fixed terminal device.

### Effects of the Invention

According to the present technology, it is possible to appropriately estimate operational states of a plurality of electrical devices connected to an electrical power line, that is, an electricity usage condition.

### BRIEF DESCRIPTION OF DRAWINGS

FIG. 1 is a block diagram showing an exemplary configuration of an operational state estimating apparatus for an electrical device as a first embodiment of the present technology.

FIG. 2 is a flow chart showing a process of estimating admittance vector time-series of a single target device in a first case where it is possible to turn off all the other connected devices (to set in a non-operational state).

FIG. 3 is a view for explaining phase adjustment of admittance vector time-series Ybef(n) and Yaft(n) in a case of estimating composite admittance vector time-series Yoth(n) of an electrical device other than the target device.

FIG. 4 is a flow chart showing a process of estimating admittance vector time-series of the single target device in a second case where there exist other connected devices that work at all times.

FIG. 5 is a schematic view of vector quantization.

FIG. 6 is a view showing an example of feature vectors registered on a feature vector database.

FIG. 7 is a view showing an integral process of an operational state estimating method in a case of a small quantity of devices.

FIG. 8 is a view showing an integral process of the operational state estimating method in a case of a large quantity of devices.

FIG. 9 is a block diagram showing an example of a computer device that executes a device registration process and an electricity usage condition determining process with software.

FIG. 10 is a block diagram showing an exemplary configuration of an operational state estimating system for an electrical device as a second embodiment.

FIG. 11 is a block diagram showing an exemplary configuration of an operational state estimating apparatus included in the operational state estimating system for the electrical device.

FIG. 12 is a block diagram showing an exemplary configuration of a server device included in the operational state estimating system for the electrical device.

### MODES FOR CARRYING OUT THE INVENTION

The following is a mode for carrying out the invention (hereinafter referred to as the “embodiment”). Explanation will be made in the following order.

1. First Embodiment

2. Second Embodiment

3. Modifications

### 1. First Embodiment

### Operational State Estimating Apparatus for Electrical Device

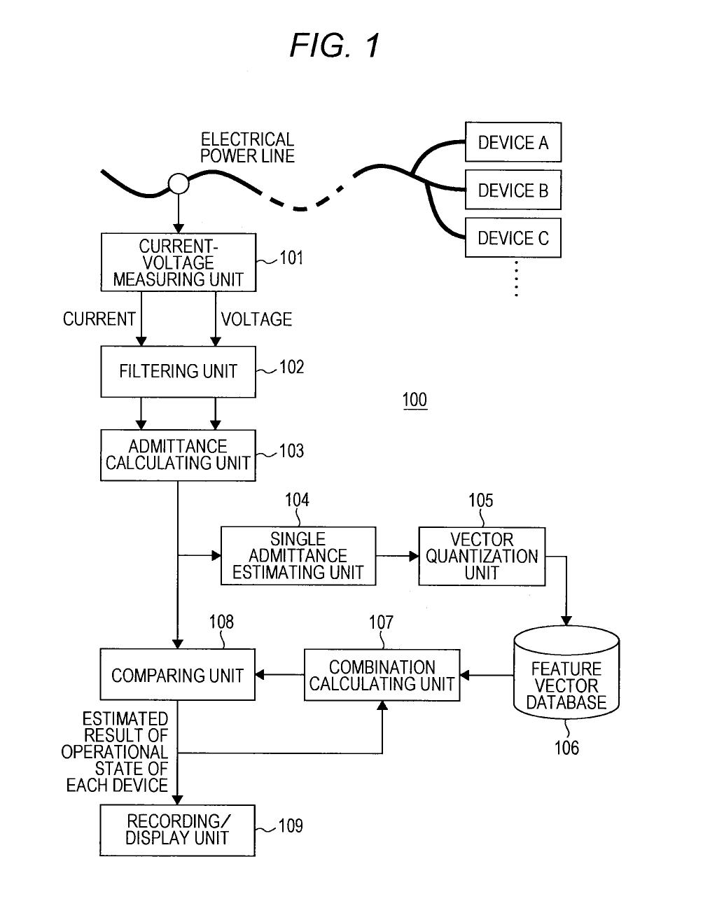

FIG. 1 is a view showing an exemplary configuration of an operational state estimating apparatus 100 for an electrical device as a first embodiment of the present technology. This operational state estimating apparatus 100 executes a device registration process and an electricity usage condition determining process. This operational state estimating apparatus 100 includes a current-voltage measuring unit 101, a filtering unit 102, an admittance calculating unit 103, a single admittance estimating unit 104, and a vector quantization unit 105. Further, the operational state estimating apparatus 100 includes a feature vector database 106, a combination calculating unit 107, a comparing unit 108, and a recording/display unit 109.

The current-voltage measuring unit 101 measures current and voltage from an electrical power line to which a plurality of electrical devices (device A, device B, device C and the like) is connected. This current-voltage measuring unit 101 measures the current and voltage values at every moment at one part of the base of the electrical power line, and obtains time-series of digital data by A/D conversion.

The filtering unit 102 filters signal components of power frequency and harmonics thereof from the time-series of the current and voltage measured by the current-voltage measuring unit 101. In other words, the filtering unit 102 calculates complex narrow-band current Ik(n) shown in the following Mathematical Formula 1 and complex narrow-band voltage Vk(n) shown in the following Mathematical Formula 2. Both of them correspond to each odd-order harmonics “k” in a time frame “n” with respect to current I(t) and voltage V(t) relating discrete-time “t”.

$$\begin{matrix}[ Mathematical Formula 1 ] & \\ {I}_{k} ( n ) = {\sum }_{t = - W / 2}^{W / 2 - 1} w ( t ) I ( t - nT ) {e}^{- j2π ( 2 k + 1 ) ft} & ( 1 ) \\ {V}_{k} ( n ) = {\sum }_{t = - W / 2}^{W / 2 - 1} w ( t ) V ( t - nT ) {e}^{- j2π ( 2 k + 1 ) ft} & ( 2 )\end{matrix}$$

Note that “n” represents a frame number, “k” represents a harmonics quantity, “f” represents power frequency (50 Hz or 60 Hz), “T” represents a time interval of the frame, “w(t)” represents a window function such as a Hann window, and “W” represents a size of the window function. To determine the harmonics, k is calculated from a range where k represents one (k=1) to a range where k represents a predetermined quantity K (k=K). Based on this calculation, Ik(n) becomes a complex time-series of current in which a narrow-band component near frequency (2k+1)f has been re-sampled at the time interval T. Similarly, Vk(n) becomes a complex time-series of voltage in which a narrow-band component near frequency (2k+1)f has been re-sampled at the time interval T.

The admittance calculating unit 103 calculates the admittance vector time-series from the signal components filtered by the filtering unit 102. In other words, the admittance calculating unit 103 calculates admittances Yk(n) in the present time “n” from the current Ik(n) and the voltage Vk(n), as shown in the following Mathematical Formula 3.

$$\begin{matrix}[ Mathematical Formula 2 ] & \\ {Y}_{k} ( n ) = \frac{{I}_{k} ( n )}{{V}_{k} ( n )} & ( 3 )\end{matrix}$$

Herein, the admittances of the calculated power frequency and the harmonics thereof are collectively described as K-dimensional vectors, as shown in the following Mathematical Formula 4, and are referred to as admittance vector time-series.

### [Mathematical Formula 3]

Y(n)=[Y₁(n),Y₂(n), . . . ,Y_{K}(n)] (4)

Processes of the current-voltage measuring unit 101, the filtering unit 102, and the admittance calculating unit 103 are common in both the device registration process and the electricity usage condition determining process. In the device registration process, admittance vector time-series of a device to be registered are estimated. Herein, a feature vector is extracted and is registered on the feature vector database 106. The single admittance estimating unit 104 and the vector quantization unit 105 function for the device registration process.

The single admittance estimating unit 104 serially sets, as a target device, the plurality of electrical devices (device A, device B, device C and like) connected to the electrical power line. Then, the single admittance estimating unit 104 estimates admittance vector time-series of the single target device.

In a first case where it is possible to turn off all the other connected devices (to set in a non-operational state), when only the target device is turned on (set in an operational state), the single admittance estimating unit 104 observes a predetermined frame quantity N of output of the admittance calculating unit 103 to obtain admittance vector time-series Y(n) of the single target device.

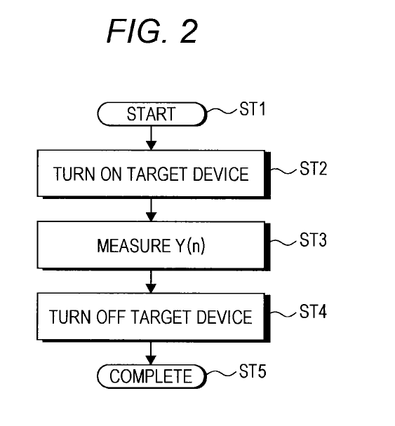

FIG. 2 is a view showing a flow chart of a process in the first case. In Step ST1, the process is started. Next, in Step ST2, the target device is turned on (set in the operational state). Next, in Step ST3, by the single admittance estimating unit 104, the predetermined frame quantity (N) of the output of the admittance calculating unit 103 is observed, and the admittance vector time-series Y(n) of the single target device are measured. Next, in Step ST4, the target device is turned off (set in the non-operational state). Finally, in Step ST5, the process is completed.

Further, in a second case where there exist other connected devices that work at all times such as a refrigerator, the single admittance estimating unit 104 cannot directly obtain the admittance vector time-series Y(n) of the single target device. Therefore, the single admittance estimating unit 104 estimates the admittance vector time-series Y(n) of the single target device as hereinafter described.

First, the single admittance estimating unit 104 observes a predetermined frame quantity (3N) or more of the output of the admittance calculating unit 103, when the target device is turned off (set in the non-operational state). Then, the single admittance estimating unit 104 obtains admittance vector time-series Ybef(n). Next, the single admittance estimating unit 104 observes the output of the admittance calculating unit 103 throughout the predetermined frame quantity (N), when the target device is turned on (operational state). Then, the single admittance estimating unit 104 obtains admittance vector time-series Yon(n). Next, the single admittance estimating unit 104 repeatedly observes the predetermined frame quantity (3N) or more of the output of the admittance calculating unit 103, when the target device is turned off (set in the non-operational state). Then, the single admittance estimating unit 104 obtains admittance vector time-series Yaft(n).

Next, the single admittance estimating unit 104 estimates composite admittance vector time-series Yoth(n) of an electrical device other than the target device by the calculation shown in the following Mathematical Formula 5.

$$\begin{matrix}[ Mathematical Formula 4 ] & \\ {Y}_{oth} ( n ) = \frac{1}{2} ( {Y}_{aft} ( n + {τ}_{aft} ) + {Y}_{bef} ( n + {τ}_{bef} ) ) ( n = 0 , … , N - 1 ) \\ ( \begin{matrix}{τ}_{aft} = {argmin}_{τ = N , … , 2 N - 1} {\sum }_{n = 0}^{N - 1} {\vert {Y}_{bef} ( n + 2 N ) - {Y}_{aft} ( n + τ ) \vert}^{2} \\ {τ}_{bef} = {argmin}_{τ = 0 , … , N - 1} {\sum }_{n = 0}^{N - 1} {\vert {Y}_{aft} ( n ) - {Y}_{bef} ( n + N + τ ) \vert}^{2}\end{matrix} ) & ( 5 )\end{matrix}$$

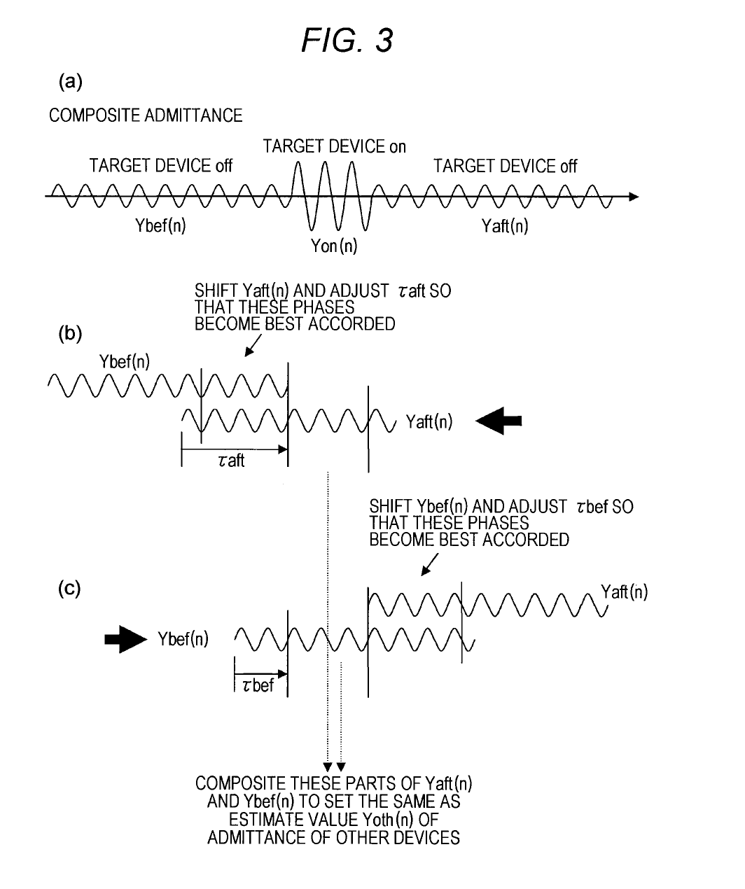

FIG. 3(a) is a view showing an example of Ybef(n), Yon(n), and Yaft(n) measured by the single admittance estimating unit 104. As shown in FIG. 3(b), τaft in Mathematical Formula 5 represents an adjusted phase amount which is best accorded with a phase of the admittance vector time-series Ybef(n) when a phase of the admittance vector time-series Yaft(n) is shifted. As shown in FIG. 3(c), τbef in Mathematical Formula 5 represents an adjusted phase amount which is best accorded with a phase of the admittance vector time-series Yaft(n) when a phase of the admittance vector time-series Ybef(n) is shifted.

The composite admittance vector time-series Yoth(n) shown in Mathematical Formula 5 is one that averages a part of the predetermined frame quantity (N) in which the admittance vector time-series Yon(n) of the phase adjusted admittance vector time-series Yaft(n) and Ybef(n) can be obtained.

Next, as shown in the following Mathematical Formula 6, the composite admittance vector time-series Yoth(n) of the electrical device other than the target device are subtracted from the admittance vector time-series Yon(n) obtained when the target device is turned on (set in the operational state). As a result, the admittance vector time-series Y(n) of the single target device are estimated.

### [Mathematical Formula 5]

Y(n)=Yₒₙ(n)−Yₒₜₕ(n) (6)

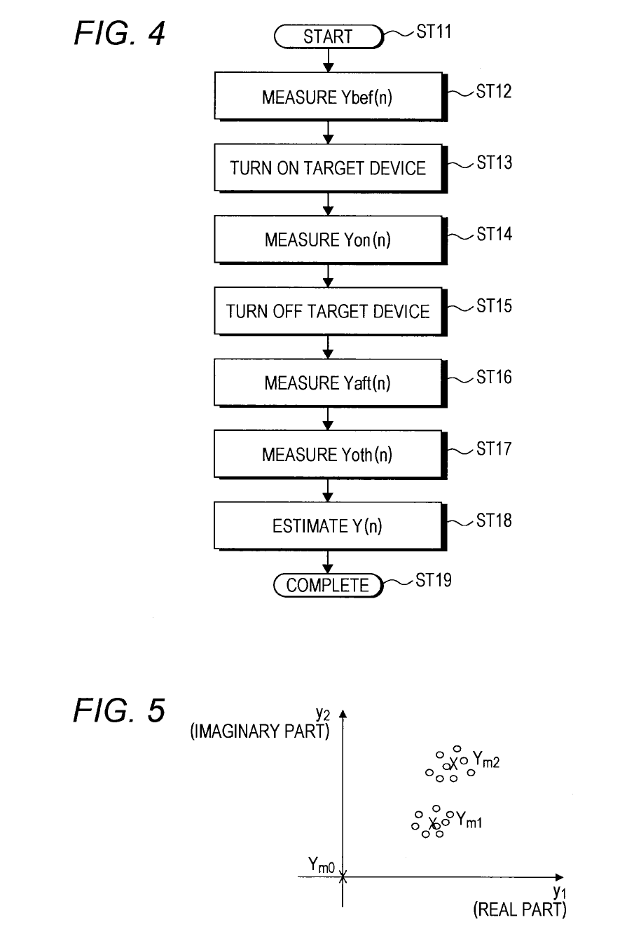

A flow chart shown in FIG. 4 illustrates a process in the second case. In Step ST11, the process is started. Next, in Step ST12, the predetermined frame quantity (3N) or more of the output of the admittance calculating unit 103 is observed, when the target device is turned off (set in the non-operational state). Then, the admittance vector time-series Ybef(n) are measured.

Next, in Step ST13, the target device is turned on (set in the operational state). Next, in Step ST14, the output of the admittance calculating unit 103 only within the predetermined frame quantity (N) is observed. Then, the admittance vector time-series Yon(n) are measured.

Next, in Step ST15, the target device is turned off (set in the non-operational state). Next, in Step ST16, the predetermined frame quantity (3N) or more of the output of the admittance calculating unit 103 is observed, when the target device is turned off (set in the non-operational state). Then, the admittance vector time-series Yaft(n) are measured.

Next, in Step ST17, the composite admittance vector time-series Yoth(n) of the electrical device other than the target device are measured by the Mathematical Formula 5. Next, in Step ST18, as shown in Mathematical Formula 6, the composite admittance vector time-series Yoth(n) are subtracted from the admittance vector time-series Yon(n). Then, the admittance vector time-series Y(n) of the single target device are estimated. Finally, in Step ST19, the process is completed.

Back to FIG. 1, the vector quantization unit 105 executes the vector quantization so that the admittance vector time-series Y(n), throughout the N frame of each device, estimated by the single admittance estimating unit 104 are represented by a predetermined quantity C (C is sufficiently smaller than N) of feature vectors. FIG. 5 is a schematic view of the vector quantization. Herein, “◯” represents admittance vector time-series Y(n) of an m-th target device, while “x” represents a vector quantized representative vector Ymc.

The vector quantization can be carried out, for example, by so-called k-means clustering such as Lloyd algorithm. Hereinafter, a total quantity of the devices is denoted by “M”, ID of the target device is denoted by “m”, the number of the feature vector is denoted by “c”, and the c-th feature vector of the m-th device is denoted by “Ymc”. Further, in order to simplify subsequent calculations, a zero vector is conveniently added as a feature vector in a case where c equals zero (c=0). Herein, Ym0 equals zero (Ym0=[0, . . . , 0]). This vector represents that the device is turned off (set in the non-operational state).

The vector quantization unit 105 carries out the above-mentioned vector quantized calculation with respect to all devices, and registers the representative vector Ymc of each device on the feature vector database 106. Accordingly, M×(C+1) quantities of the feature vectors are registered on the feature vector database. Herein, “m” of “Ymc” represents from one to “M”, while “c” thereof represents from zero to “C” (m=1, . . . M, c=0, . . . C).

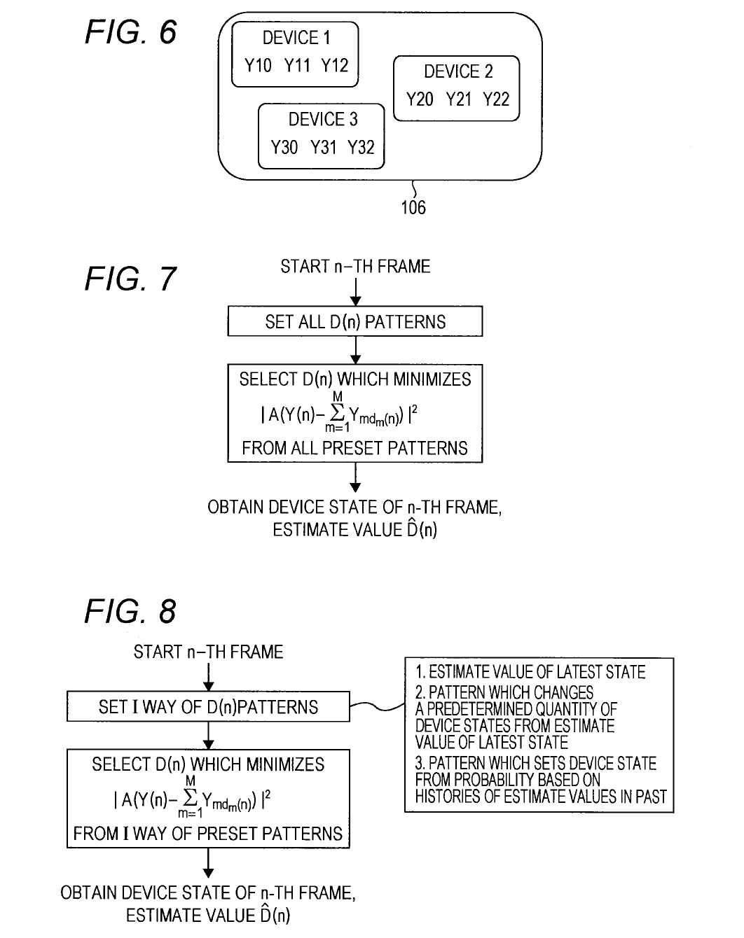

FIG. 6 is a view showing an example of the feature vectors registered on the feature vector database 106. The example shows a case where M (device quantity) is three (M=3), and C (vector quantity when each device is in the operational state) is two (C=2). The feature vector Ym0 and vectors Ym1, Ym2 are registered per device. The feature vector Ym0 represents that the device is turned off (set in the non-operational state), while the vectors Ym1, Ym2 represent that the device is turned on (in the operational state).

In the electricity usage condition determining process, the admittance vector time-series Y(n) of all devices that are used are observed at every moment. Accordingly to the current adding law, all the admittances are approximately similar to a sum of the admittance at each time of each device. Therefore, in the electricity usage condition determining process, distances are calculated between the observed admittance vectors and vectors in which a sum is calculated by variously changing the combinations of the registered (retained) feature vectors. A combination having the shortest distance is searched to estimate the operational state of each device.

Hereinafter, an operational state vector representing the operational state at each time (frame) of each device is denoted by D(n)=[d1, . . . , dM] (“dm” represents any one of values of the operational state from 0, to C). Herein, “M” represents the quantity of the registered devices, “m” represents the number of the devices, and “n” represents the number of the frame.

In this occasion, a problem for estimating the operational state (usage condition) of each device based on the observed admittance vector time-series Y(n) can be described as a problem for solving D(n)(̂) in the following Mathematical Formula 7. Note that “A” is a load matrix determined in advance. Simply, an identity matrix or some preset weighting matrices may be used as well.

$$\begin{matrix}[ Mathematical Formula 6 ] & \\ \hat{D} ( n ) = {argmin}_{{d}_{m} = 0 , … , C} {\vert A ( Y ( n ) - {\sum }_{m = 1}^{M} {Y}_{{md}_{m}} ) \vert}^{2} & ( 7 )\end{matrix}$$

The combination calculating unit 107 and the comparing unit 108 function for the electricity usage condition determining process.

The combination calculating unit 107 calculates the combination patterns of the feature vectors of the plurality of electrical devices registered (retained) on the feature vector database 106. In other words, the combination calculating unit 107 calculates a sum of the feature vectors in each combination pattern.

The comparing unit 108 compares the feature vectors (sum of the feature vectors) combined by the combination calculating unit 107 with the admittance vector time-series Y(n) calculated by the admittance estimating unit 103. Then, the comparing unit 108 obtains an estimated result of the operational states (electricity usage condition) of the plurality of electrical devices. In other words, the comparing unit 108 determines D(n)(̂) in the above-mentioned Mathematical Formula 7 in each frame n.

Herein, processes of the combination calculating unit 107 and the comparing unit 108 are different as hereinafter described, depending on the quantity of the devices.

“In a Case of a Small Quantity of Devices”

In a case of a small quantity of devices, more specifically, in cases where the calculation in the above-mentioned Mathematical Formula 7 can be completed with respect to all operational state patterns that d1, . . . , dM may take within the frame interval T, it is possible to carry out exhaustive search of a device state.

In this occasion, the combination calculating unit 107 calculates the sum of the feature vectors with respect to all the combination patters of d1, . . . , dM, as shown in the following Mathematical Formula 8. The comparing unit 108 estimates the operational state (electricity usage condition) of each device in the present time n by searching D(n)(̂) that maximizes the Mathematical Formula 7.

$$\begin{matrix}[ Mathematical Formula 7 ] & \\ Sum of the feature vectors = {\sum }_{m = 1}^{M} {Y}_{{md}_{m}} & ( 8 )\end{matrix}$$

“In a Case of a Large Quantity of Devices”

There are M-th power of (C+1) ways for all the operational state patterns that d1, . . . , dM may take, and the patterns exponentially increase when the quantity of the devices increases. Therefore, in a case of a large quantity of devices, it is practically difficult to search all within the finite frame interval T. Therefore, the combination calculating unit 107 takes a method that chooses, within a feasible range, stochastically possible combination patterns of the operational states based on the operational state (electricity usage condition), which is estimated at the present time, of each device.

An estimate value of the latest device state is represented by D(n−1). The combination calculating unit 107 calculates a predetermined I way of D(n) test patterns based on D(n−1), in the following order (1), (2), and (3).

(1) a pattern which does not change each elemental state of D(n−1)

(2) a pattern which changes X quantities or less of each elemental state of D(n−1)

(3) a pattern which sets each element of D(n−1) by random numbers in accordance with predetermined probability P(dmc)

The above-mentioned “I” and “X” are numbers that do not exceed numbers which can be calculated within the frame interval T. Further, the numbers of “I” and “X” are determined by a function of a calculator that is used practically. Further, the probability P(dmc) that generates the random numbers can be set by a method in which a histogram relating each state dmc of each device is obtained with respect to an estimate value D(n) of the device state in the past, and the histogram is normalized so that a sum becomes one. When practically using in a household, there occurs a deviation of the device usage condition depending on time and day. Therefore, it is effective to apply a method in which the above-mentioned histogram is aggregated according to day and time, and probability distribution is used by switching depending on the present time (day or time).

The combination calculating unit 107 calculates the sum of the feature vectors with respect to the above-mentioned I way of the combination patterns, as shown in the above-mentioned Mathematical Formula 8. The comparing unit 108 estimates the operational state (electricity usage condition) of each device in the present time n by searching D(n)(̂) that maximizes the Mathematical Formula 7.

FIG. 7 is a view showing an integral process of an operational state estimating method in a case of a small quantity of devices. FIG. 8 is a view showing an integral process of the operational state estimating method in a case of a large quantity of devices.

Back to FIG. 1, the recording/display unit 109 records, on a recording medium, the estimated result of the operational state (electricity usage condition) of each device obtained by the comparing unit 108 together with time, and displays the same on a display. As a result, a history of the operational state of each device can be stored. Further, a user can easily grasp the present operational state (electricity usage condition) of each device. In such a case, not only the operational state (electricity usage condition) of each device, but also electricity usage may be recorded or displayed.

The electricity usage in an n-th frame of each device can be calculated from the following Mathematical Formula 9 by using the estimate value D(n)(̂)=(d1, . . . , dM) of each device state. Note that Ymdmk is an element corresponding to k-th harmonics of a feature vector Ymdm when an m-th device is in a dm state.

$$\begin{matrix}[ Mathematical Formula 8 ] & \\ {P}_{m} ( n ) = {\sum }_{k = 1}^{K} {Y}_{{md}_{m} k} {V}_{k}^{2} ( n ) & ( 9 )\end{matrix}$$

Hereinafter, an operation of the above-mentioned operational state estimating apparatus 100 for the electrical device shown in FIG. 1 will be described. First, an operation in the device registration process will be described. In the current-voltage measuring unit 101, the current and voltage values at every moment are measured at one part of the base of the electrical power line. These measured values are supplied to the filtering unit 102. In the filtering unit 102, the signal components of the power frequency and the harmonics thereof are filtered from the time-series measured values of the current and voltage (see Mathematical Formulas 1 and 2).

The signal components filtered by the filtering unit 102 are supplied to the admittance calculating unit 103. In the admittance calculating unit 103, admittances Yk(n) of the present time n are calculated based on the signal components filtered by the filtering unit 102 (see Mathematical Formula 3). The admittance vector time-series Y(n) obtained by the admittance calculating unit 103 are supplied to the single admittance estimating unit 104.

In the single admittance estimating unit 104, based on the admittance vector time-series Y(n), the plurality of electrical devices (device A, device B, device C and the like) connected to the electrical power line is serially set as the target device. Herein, admittance vector time-series of the single target device are estimated. The admittance vector time-series of the single target device are supplied to the vector quantization unit 105.

In the vector quantization unit 105, the vector quantization is carried out so that the admittance vector time-series Y(n), throughout the N frame of each device, estimated by the single admittance estimating unit 104 are represented by the predetermined quantity C (C is sufficiently smaller than N) of the feature vectors. Further, in the vector quantization unit 105, the representative vector Ymc of each device is registered on the feature vector database 106.

Next, an operation in the electricity usage condition determining process will be described. In the current-voltage measuring unit 101, the current and voltage values at every moment are measured at one part of the base of the electrical power line. These measured values are supplied to the filtering unit 102. In the filtering unit 102, the signal components of the power frequency and the harmonics thereof are filtered from the time-series measured values of the current and voltage (see Mathematical Formulas 1 and 2).

The signal components filtered by the filtering unit 102 are supplied to the admittance calculating unit 103. In the admittance calculating unit 103, admittances Yk(n) of the present time n are calculated based on the signal components filtered by the filtering unit 102 (see Mathematical Formula 3). The admittance vector time-series Y(n) obtained by the admittance calculating unit 103 are supplied to the comparing unit 108.

In the combination calculating unit 107, the combination patterns, of the feature vectors of the plurality of electrical devices, which have been registered (retained) on the feature vector database 106 are calculated. In the comparing unit 108, the feature vectors (sum of the feature vectors) combined by the combination calculating unit 107 are compared with the admittance vector time-series Y(n) calculated by the admittance calculating unit 103. Then, the estimated result of the operational states (electricity usage condition) of the plurality of electrical devices is obtained (see Mathematical Formula 7).

The estimated result of the operational states (electricity usage condition) of the plurality of electrical devices obtained by the comparing unit 108 are supplied to the recording/display unit 109. In the recording/display unit 109, the estimated result of the operational state (electricity usage condition) of each device obtained by the comparing unit 108 is recorded together with the time, and is displayed on the display.

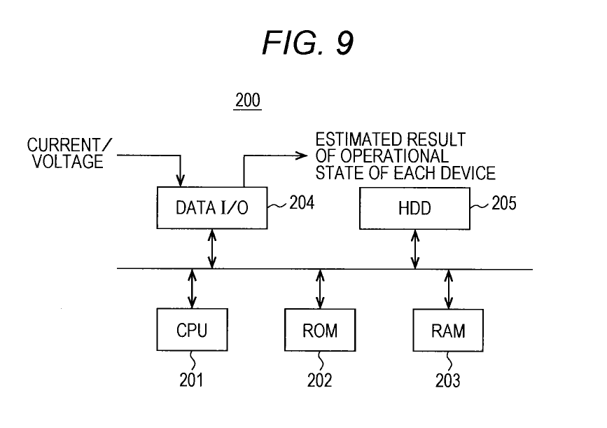

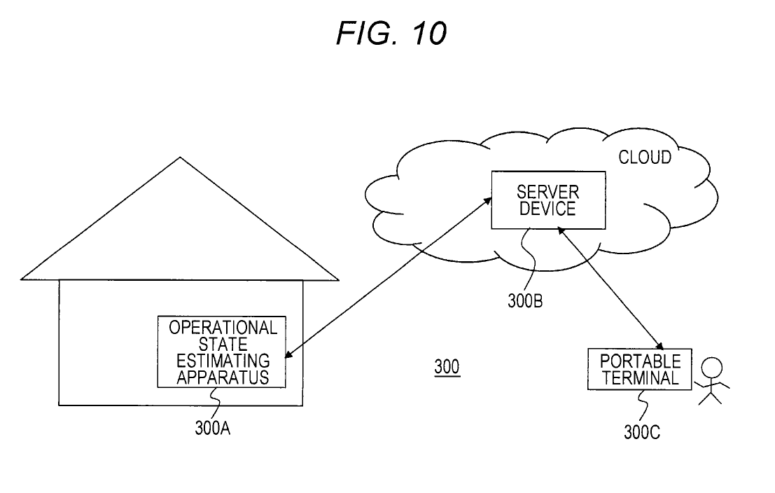

Note that the operational state estimating apparatus 100 shown in FIG. 1 may include hardware, and at least a part of the apparatus may include software. For example, a computer device 200 shown in FIG. 9 can be configured to function as each part in the operational state estimating apparatus 100 shown in FIG. 1, that is, from the filtering unit 102 to the comparing unit 108, so as to execute the device registration process and the electricity usage condition determining process similar to the above-mentioned processes.

The computer device 200 includes a central processing unit (CPU) 201, a random access memory (RAM) 202, a read only memory (ROM) 203, a data input/output unit (data I/O) 204, and a hard disk drive (HDD) 205. In the ROM 202, a processing program of the CPU 201 and the like are stored. The RAM 203 functions as a work area of the CPU 201. The CPU 201 reads out the processing program stored in the ROM 202, as necessary, and forwards the readout processing program to the RAM 203 to decompress the same. Then, the CPU 201 reads out the decompressed processing program to execute the processing.

In the computer device 200, the current and voltage of the time-series measured by the current-voltage measuring unit 101 are input through the data I/O 204 and are accumulated in the HDD 205. The CPU 201 executes the device registration process and the electricity usage condition determining process with respect to the time-series data of the current and voltage accumulated in the HDD 205. Then, the estimated result of the operational state of each device is output to outside through the data I/O 204.

As mentioned above, in the operational state estimating apparatus 100 for the electrical device shown in FIG. 1, the admittance vector time-series obtained based on the current and voltage measured by the electrical power line are compared with the combinations of the feature vectors of the plurality of electrical devices connected to the electrical power line. Then, the estimated result of the operational states of the plurality of electrical devices is obtained. Accordingly, it is possible to appropriately estimate the operational states (electricity usage condition) of the plurality of electrical devices. Further, the operational state (electricity usage condition) of each device in a household can be easily visualized, and electricity can be effectively saved. Moreover, it is possible to grasp the electricity usage condition of each electrical device in a household, and to supply electricity flexibly.

### 2. Second Embodiment

### Operational State Estimating System for Electrical Device

FIG. 10 is a view showing an exemplary configuration of an operational state estimating system 300 for an electrical device as a second embodiment of the present technology. This operational state estimating system 300 includes an operational state estimating apparatus 300A for an electrical device disposed in a household, a server device 300B in cloud, and a portable terminal 300C.

In the operational state estimating system 300, the server device 300B estimates the operational states of a plurality of electrical devices connected to an electrical power line from admittance vector time-series. Therefore, the operational state estimating apparatus 300A transmits admittance vector time-series Y(n) to the server device 300B, and receives an estimated result of the operational state (electricity usage condition) of each device from the server device 300B.

Further, the operational state estimating system 300 can carry out request-to-send of the estimated result of the operational state of the plurality of electrical devices to the server device 300B from the portable terminal 300C, that is, another terminal device different from the operational state estimating apparatus 300A. This portable terminal 300C receives the estimated result, and is capable of, for example, displaying the same.

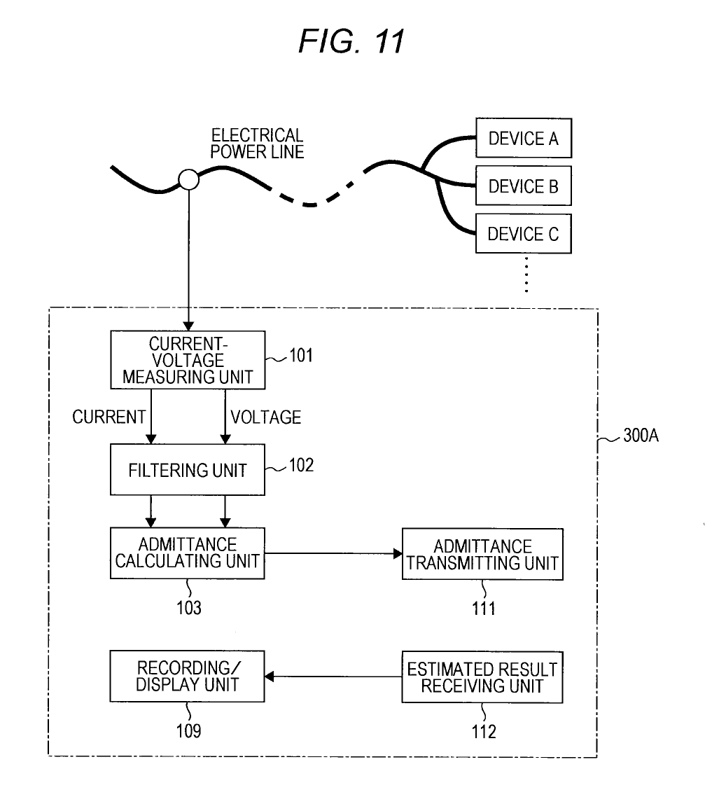

FIG. 11 is a view showing an exemplary configuration of the operational state estimating apparatus 300A. In FIG. 11, the same components as those shown in FIG. 1 are denoted by the same reference numerals as those used in FIG. 1, and explanation of them is not repeated herein. This operational state estimating apparatus 300A includes a current-voltage measuring unit 101, a filtering unit 102, an admittance calculating unit 103, an admittance transmitting unit 111, an estimated result receiving unit 112, and a recording/display unit 109.

The admittance transmitting unit 111 transmits the admittance vector time-series Y (n) obtained by the admittance calculating unit 103 to the server device 300B in the cloud. The estimated result receiving unit 112 receives the estimated result of the operational state (electricity usage condition) of each electrical device transmitted from the server device 300B in the cloud. Then, the estimated result receiving unit 112 supplies the estimated result to the recording/display unit 109.

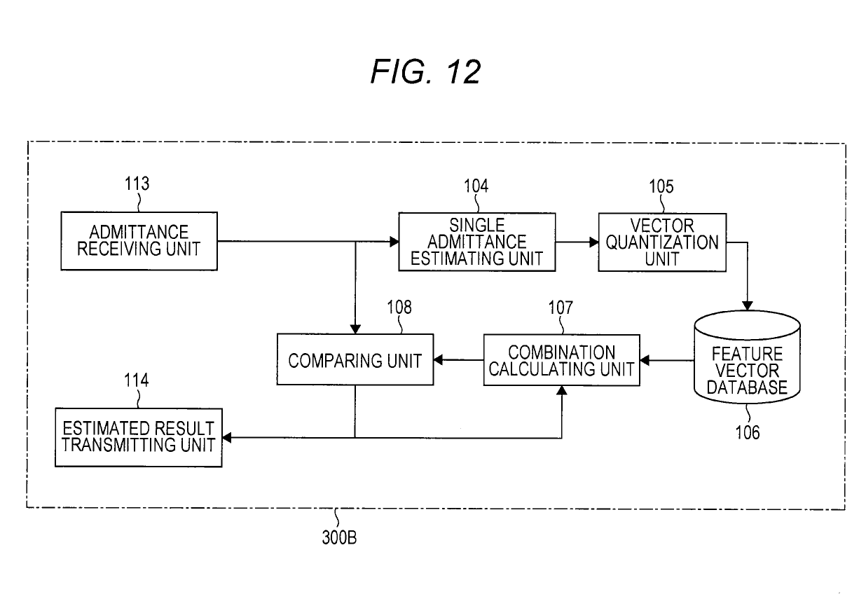

FIG. 12 is a view showing an exemplary configuration of the server device 300B. In FIG. 12, the same components as those shown in FIG. 1 are denoted by the same reference numerals as those used in FIG. 1, and explanation of them is not repeated herein. This server device 300B includes an admittance receiving unit 113, a single admittance estimating unit 104, a vector quantization unit 105, a feature vector database 106, a combination calculating unit 107, a comparing unit 108, and an estimated result transmitting unit 114.

The admittance receiving unit 113 receives the admittance vector time-series Y(n) transmitted from the operational state estimating apparatus 300A. Then, the admittance receiving unit 113 supplies the admittance vector time-series Y(n) to the single admittance estimating unit 104 and the comparing unit 108. The estimated result transmitting unit 114 transmits the estimated result of the operational state (electricity usage condition) of each electrical device obtained by the comparing unit 108 to the operational state estimating apparatus 300A.

Although detailed description will be omitted, the operational state estimating system 300 for the electrical device shown in FIG. 10 executes the device registration process and the electricity usage condition determining process in a similar way as the operational state estimating apparatus 100 for the electrical device shown in FIG. 1. Accordingly, it is possible to appropriately estimate the operational states of the plurality of electrical devices, that is, the electricity usage condition.

Further, in the operational state estimating system 300 for the electrical device shown in FIG. 10, instead of the operational state estimating apparatus 300A, the server device 300B in the cloud carries out a process of estimating the operational states (electricity usage condition) of the plurality of electrical devices connected to the electrical power line from the admittance vector time-series Y(n). Accordingly, it is possible to reduce a processing load of the operational state estimating apparatus 300A, and also to provide the estimated result from the server device 300B to the operational state estimating apparatus 300A with high accuracy due to a high-performance process.

Further, in the operational state estimating system 300 for the electrical device shown in FIG. 10, the request-to-send of the estimated result can be transmitted from portable terminal 300C to the server device 300B, and the estimated result can be received. Accordingly, it is possible for a user to confirm the estimated result of the operational states of the plurality of electrical devices even from the place where he/she is, by using the portable terminal 300C but not the fixed operational state estimating apparatus 300A.

### 3. Modifications

In the above-mentioned embodiments, the examples with executive functions of both the device registration process and the electricity usage condition determining process have been described. However, for example, an example with only the executive function of the electricity usage condition determining process can also be taken into consideration. In such a case, the feature vector of each device is registered and retained in the feature vector database 106 by some method.

The present technology may further be embodied in the structures described below.

(1) An operational state estimating apparatus for an electrical device, including:

a current-voltage measuring unit configured to measure current and voltage as time-series from an electrical power line to which a plurality of electrical devices is connected;

a filtering unit configured to filter signal components of power frequency and harmonics thereof from the time-series of the measured current and voltage;

an admittance calculating unit configured to calculate admittance vector time-series from the filtered signal components;

a feature vector retaining unit configured to retain feature vectors of the plurality of electrical devices;

a combination calculating unit configured to calculate combination patterns of the retained feature vectors of the plurality of electrical devices; and

a comparing unit configured to compare the combined feature vectors and the calculated admittance vector time-series to obtain an estimated result of the operational states of the plurality of electrical devices.

(2) The operational state estimating apparatus for the electrical device according to (1), wherein the feature vector of a predetermined electrical device includes one or a plurality of feature vectors extracted by vector quantization from the admittance vector time-series in a case where the predetermined electrical device is in the operational state.

(3) The operational state estimating apparatus for the electrical device according to (1) or (2), wherein the combination calculating unit calculates all the combination patterns of the retained feature vectors.

(4) The operational state estimating apparatus for the electrical device according to (1) or (2), wherein the combination calculating unit calculates combination patterns, in which the operational states of the devices have been stochastically changed, from an estimated result of the latest device operational state based on combination patterns in which the operational states of the devices within a predetermined quantity have been changed and/or based on a predetermined probability distribution.

(5) The operational state estimating apparatus for the electrical device according to (4), wherein the predetermined probability distribution is calculated from past histories of the operational states of the plurality of electrical devices.

(6) The operational state estimating apparatus for the electrical device according to (4), wherein the predetermined probability distribution is one that is selected according to time from a plurality of probability distributions calculated according to day and time.

(7) The operational state estimating apparatus for the electrical device according to any one of (1) to (6), wherein the comparing unit calculates inter-vector distances between the combined feature vectors and the calculated admittance vector time-series, and sets a combination having the shortest distance as the estimated result of the operational states of the plurality of electrical devices.

(8) An operational state estimating method for an electrical device, including:

a current/voltage measuring step for measuring current and voltage as time-series from an electrical power line to which a plurality of electrical devices is connected;

a filtering step for filtering signal components of power frequency and harmonics thereof from the time-series of the measured current and voltage;

an admittance calculating step for calculating admittance vector time-series from the filtered signal components;

a combination calculating step for calculating combination patterns of retained feature vectors of the plurality of electrical devices; and

a comparing step for comparing the combined feature vectors and the calculated admittance vector time-series to obtain an estimated result of the operational states of the plurality of electrical devices.

(9) A program that makes a computer function as:

a filtering means for filtering signal components of power frequency and harmonics thereof from time-series of current and voltage measured from an electrical power line to which a plurality of electrical devices is connected;

an admittance calculating means for calculating admittance vector time-series from the filtered signal components;

an admittance vector retaining means for retaining feature vectors of the plurality of electrical devices;

a combination calculating means for calculating combination patterns of the retained feature vectors of the plurality of electrical devices; and

a comparing means comparing the combined feature vectors and the calculated admittance vector time-series to obtain an estimated result of the operational states of the plurality of electrical devices.

(10) A feature vector registering apparatus for an electrical device, including:

a current-voltage measuring unit configured to measure current and voltage as time-series from an electrical power line to which a plurality of electrical devices is connected;

a filtering unit configured to filter signal components of power frequency and harmonics thereof from the time-series of the measured current and voltage;

an admittance calculating unit configured to calculate admittance vector time-series from the filtered signal components;

a feature vector extracting unit configured to extract feature vectors of each of the plurality of electrical devices from the calculated admittance vector time-series; and

a feature vector registering unit configured to register, on a database, the extracted feature vectors of the plurality of electrical devices.

(11) The feature vector registering apparatus for the electrical device according to (10), wherein the feature vector extracting unit extracts one or a plurality of feature vectors, as a feature vector of a predetermined electrical device, from the calculated admittance vector time-series by vector quantization.

(12) The feature vector registering apparatus for the electrical device according to (10), wherein the feature vector extracting unit estimates admittance vector time-series of a predetermined electrical device from the calculated admittance vector time-series, and extracts one or a plurality of feature vectors, as a feature vector of the predetermined electrical device, from the estimated admittance vector time-series by vector quantization.

(13) The feature vector registering apparatus for the electrical device according to (12), wherein the feature vector extracting unit estimates admittance vector time-series of an electrical device other than the predetermined electrical device from the calculated admittance vector time-series in a case where the predetermined electrical device is not in an operational state, and estimates the admittance vector time-series of the predetermined electrical device from the calculated admittance vector time-series in a case where the predetermined electrical device is in the operational state by removing an estimate value of the estimated admittance vector time-series of the electrical device other than the predetermined electrical device.

(14) The feature vector registering apparatus for the electrical device according to (13), wherein the feature vector extracting unit estimates the admittance vector time-series of the electrical device other than the predetermined electrical device by according and compositing phases of the calculated admittance vector time-series in time periods before and after driving the predetermined electrical device so that a correlation value of the admittance vector time-series becomes the highest.

(15) A feature vector registering method for an electrical device, including:

a current-voltage measuring step for measuring current and voltage as time-series from an electrical power line to which a plurality of electrical devices is connected;

a filtering step for filtering signal components of power frequency and harmonics thereof from the time-series of the measured current and voltage;

an admittance calculating step for calculating admittance vector time-series from the filtered signal components;

a feature vector extracting step for extracting feature vectors of each of the plurality of electrical devices from the calculated admittance vector time-series; and

a feature vector registering step for registering, on a database, the extracted feature vectors of the plurality of electrical devices.

(16) An operational state estimating apparatus for an electrical device, including:

a current-voltage measuring unit configured to measure current and voltage as time-series from an electrical power line to which a plurality of electrical devices is connected;

a filtering unit configured to filter signal components of power frequency and harmonics thereof from the time-series of the measured current and voltage;

an admittance calculating unit configured to calculate admittance vector time-series from the filtered signal components;

a feature vector extracting unit configured to extract feature vectors of each of the plurality of electrical devices from the calculated admittance vector time-series;

a feature vector retaining unit configured to retain the extracted feature vectors of each of the plurality of electrical devices;

a combination calculating unit configured to calculate combination patterns of the retained feature vectors of the plurality of electrical devices; and

a comparing unit configured to compare the combined feature vectors and the calculated admittance vector time-series to obtain an estimated result of the operational states of the plurality of electrical devices.

(17) An operational state estimating apparatus for an electrical device, including:

a current-voltage measuring unit configured to measure current and voltage as time-series from an electrical power line to which a plurality of electrical devices is connected;

a filtering unit configured to filter signal components of power frequency and harmonics thereof from the time-series of the measured current and voltage;

an admittance calculating unit configured to calculate admittance vector time-series from the filtered signal components;

an admittance transmitting unit configured to transmit the calculated admittance vector time-series to a server device; and

an estimated result receiving unit configured to receive an estimated result of the operational states of the plurality of electrical devices from the server device.

(18) A server device, including:

an admittance receiving unit configured to receive admittance vector time-series transmitted from a terminal device;

a feature vector retaining unit configured to retain feature vectors of a plurality of electrical devices;

a combination calculating unit configured to calculate combination patterns of the retained feature vectors of the plurality of electrical devices;

a comparing unit configured to compare the combined feature vectors and the received admittance vector time-series to obtain an estimated result of the operational states of the plurality of electrical devices; and

an estimated result transmitting unit configured to transmit the obtained estimated result of the operational states of the plurality of electrical devices to the terminal device.

(19) The server device according to (18), further including a request-to-send receiving unit configured to receive a request-to-send of the estimated result transmitted from another terminal device different from the terminal device, wherein the estimated result transmitting unit transmits the obtained estimated result of the operational states of the plurality of electrical devices to the other terminal device based on the received request-to-send.

(20) An operational state estimating system for an electrical device including a terminal device and a server device, wherein the terminal device includes:

a current-voltage measuring unit configured to measure current and voltage as time-series from an electrical power line to which a plurality of electrical devices is connected;

a filtering unit configured to filter signal components of power frequency and harmonics thereof from the time-series of the measured current and voltage;

an admittance calculating unit configured to calculate admittance vector time-series from the filtered signal components;

an admittance transmitting unit configured to transmit the calculated admittance vector time-series to the server device; and

an estimated result receiving unit configured to receive an estimated result of the operational states of the plurality of electrical devices from the server device,

wherein the server device includes:

an admittance receiving unit configured to receive the admittance vector time-series transmitted from the terminal device;

a feature vector retaining unit configured to retain feature vectors of the plurality of electrical devices;

a combination calculating unit configured to calculate combination patters of the retained feature vectors of the plurality of electrical devices;

a comparing unit configured to compare the combined feature vectors and the received admittance vector time-series to obtain the estimated result of the operational states of the plurality of electrical devices; and

an estimated result transmitting unit configured to transmit the obtained estimated result of the operational states of the plurality of electrical devices to the terminal device.

### REFERENCE SIGNS LIST

100 Operational state estimating apparatus for an electrical device
101 Current-voltage measuring unit
102 Filtering unit
103 Admittance calculating unit
104 Single admittance estimating unit
105 Vector quantization unit
106 Feature vector database
107 Combination calculating unit
108 Comparing unit
109 Recording/display unit
111 Admittance transmitting unit
112 Estimated result receiving unit
113 Admittance receiving unit
114 Estimated result transmitting unit
200 Computer device
201 CPU
202 ROM
203 RAM
204 Data I/O
205 HDD
300 Operational state estimating system for an electrical device
300A Operational state estimating apparatus for an electrical device
300B Server device
300C Portable terminal

1. An operational state estimating apparatus for an electrical device, comprising:
a current-voltage measuring unit configured to measure current and voltage as time-series from an electrical power line to which a plurality of electrical devices is connected;
a filtering unit configured to filter signal components of power frequency and harmonics thereof from the time-series of the measured current and voltage;
an admittance calculating unit configured to calculate admittance vector time-series from the filtered signal components;
a feature vector retaining unit configured to retain feature vectors of the plurality of electrical devices;
a combination calculating unit configured to calculate combination patterns of the retained feature vectors of the plurality of electrical devices; and
a comparing unit configured to compare the combined feature vectors and the calculated admittance vector time-series to obtain an estimated result of the operational states of the plurality of electrical devices.

2. The operational state estimating apparatus for the electrical device according to claim 1, wherein the feature vector of a predetermined electrical device includes one or a plurality of feature vectors extracted by vector quantization from the admittance vector time-series in a case where the predetermined electrical device is in the operational state.

3. The operational state estimating apparatus for the electrical device according to claim 1, wherein the combination calculating unit calculates all the combination patterns of the retained feature vectors.

4. The operational state estimating apparatus for the electrical device according to claim 1, wherein the combination calculating unit calculates combination patterns, in which the operational states of the devices have been stochastically changed, from an estimated result of the latest device operational state based on combination patterns in which the operational states of the devices within a predetermined quantity have been changed and/or based on a predetermined probability distribution.

5. The operational state estimating apparatus for the electrical device according to claim 4, wherein the predetermined probability distribution is calculated from past histories of the operational states of the plurality of electrical devices.

6. The operational state estimating apparatus for the electrical device according to claim 4, wherein the predetermined probability distribution is one that is selected according to time from a plurality of probability distributions calculated according to day and time.

7. The operational state estimating apparatus for the electrical device according to claim 1, wherein the comparing unit calculates inter-vector distances between the combined feature vectors and the calculated admittance vector time-series, and sets a combination having the shortest distance as the estimated result of the operational states of the plurality of electrical devices.

8. An operational state estimating method for an electrical device, comprising:
a current/voltage measuring step for measuring current and voltage as time-series from an electrical power line to which a plurality of electrical devices is connected;
a filtering step for filtering signal components of power frequency and harmonics thereof from the time-series of the measured current and voltage;
an admittance calculating step for calculating admittance vector time-series from the filtered signal components;
a combination calculating step for calculating combination patterns of retained feature vectors of the plurality of electrical devices; and
a comparing step for comparing the combined feature vectors and the calculated admittance vector time-series to obtain an estimated result of the operational states of the plurality of electrical devices.

9. A program that makes a computer function as:
a filtering means for filtering signal components of power frequency and harmonics thereof from time-series of current and voltage measured from an electrical power line to which a plurality of electrical devices is connected;
an admittance calculating means for calculating admittance vector time-series from the filtered signal components;
an admittance vector retaining means for retaining feature vectors of the plurality of electrical devices;
a combination calculating means for calculating combination patterns of the retained feature vectors of the plurality of electrical devices; and
a comparing means comparing the combined feature vectors and the calculated admittance vector time-series to obtain an estimated result of the operational states of the plurality of electrical devices.

10. A feature vector registering apparatus for an electrical device, comprising:
a current-voltage measuring unit configured to measure current and voltage as time-series from an electrical power line to which a plurality of electrical devices is connected;
a filtering unit configured to filter signal components of power frequency and harmonics thereof from the time-series of the measured current and voltage;
an admittance calculating unit configured to calculate admittance vector time-series from the filtered signal components;
a feature vector extracting unit configured to extract feature vectors of each of the plurality of electrical devices from the calculated admittance vector time-series; and
a feature vector registering unit configured to register, on a database, the extracted feature vectors of the plurality of electrical devices.

11. The feature vector registering apparatus for the electrical device according to claim 10, wherein the feature vector extracting unit extracts one or a plurality of feature vectors, as a feature vector of a predetermined electrical device, from the calculated admittance vector time-series by vector quantization.

12. The feature vector registering apparatus for the electrical device according to claim 10, wherein the feature vector extracting unit estimates admittance vector time-series of a predetermined electrical device from the calculated admittance vector time-series, and extracts one or a plurality of feature vectors, as a feature vector of the predetermined electrical device, from the estimated admittance vector time-series by vector quantization.

13. The feature vector registering apparatus for the electrical device according to claim 12, wherein the feature vector extracting unit estimates admittance vector time-series of an electrical device other than the predetermined electrical device from the calculated admittance vector time-series in a case where the predetermined electrical device is not in an operational state, and estimates the admittance vector time-series of the predetermined electrical device from the calculated admittance vector time-series in a case where the predetermined electrical device is in the operational state by removing an estimate value of the estimated admittance vector time-series of the electrical device other than the predetermined electrical device.

14. The feature vector registering apparatus for the electrical device according to claim 13, wherein the feature vector extracting unit estimates the admittance vector time-series of the electrical device other than the predetermined electrical device by according and compositing phases of the calculated admittance vector time-series in time periods before and after driving the predetermined electrical device so that a correlation value of the admittance vector time-series becomes the highest.

15. A feature vector registering method for an electrical device, comprising:
a current-voltage measuring step for measuring current and voltage as time-series from an electrical power line to which a plurality of electrical devices is connected;
a filtering step for filtering signal components of power frequency and harmonics thereof from the time-series of the measured current and voltage;
an admittance calculating step for calculating admittance vector time-series from the filtered signal components;
a feature vector extracting step for extracting feature vectors of each of the plurality of electrical devices from the calculated admittance vector time-series; and
a feature vector registering step for registering, on a database, the extracted feature vectors of the plurality of electrical devices.

16. An operational state estimating apparatus for an electrical device, comprising:
a current-voltage measuring unit configured to measure current and voltage as time-series from an electrical power line to which a plurality of electrical devices is connected;
a filtering unit configured to filter signal components of power frequency and harmonics thereof from the time-series of the measured current and voltage;
an admittance calculating unit configured to calculate admittance vector time-series from the filtered signal components;
a feature vector extracting unit configured to extract feature vectors of each of the plurality of electrical devices from the calculated admittance vector time-series;
a feature vector retaining unit configured to retain the extracted feature vectors of each of the plurality of electrical devices;
a combination calculating unit configured to calculate combination patterns of the retained feature vectors of the plurality of electrical devices; and
a comparing unit configured to compare the combined feature vectors and the calculated admittance vector time-series to obtain an estimated result of the operational states of the plurality of electrical devices.

17. An operational state estimating apparatus for an electrical device, comprising:
a current-voltage measuring unit configured to measure current and voltage as time-series from an electrical power line to which a plurality of electrical devices is connected;
a filtering unit configured to filter signal components of power frequency and harmonics thereof from the time-series of the measured current and voltage;
an admittance calculating unit configured to calculate admittance vector time-series from the filtered signal components;
an admittance transmitting unit configured to transmit the calculated admittance vector time-series to a server device; and
an estimated result receiving unit configured to receive an estimated result of the operational states of the plurality of electrical devices from the server device.

18. A server device, comprising:
an admittance receiving unit configured to receive admittance vector time-series transmitted from a terminal device;
a feature vector retaining unit configured to retain feature vectors of a plurality of electrical devices;
a combination calculating unit configured to calculate combination patterns of the retained feature vectors of the plurality of electrical devices;
a comparing unit configured to compare the combined feature vectors and the received admittance vector time-series to obtain an estimated result of the operational states of the plurality of electrical devices; and
an estimated result transmitting unit configured to transmit the obtained estimated result of the operational states of the plurality of electrical devices to the terminal device.

19. The server device according to claim 18, further comprising a request-to-send receiving unit configured to receive a request-to-send of the estimated result transmitted from another terminal device different from the terminal device, wherein the estimated result transmitting unit transmits the obtained estimated result of the operational states of the plurality of electrical devices to the other terminal device based on the received request-to-send.

20. An operational state estimating system for an electrical device comprising a terminal device and a server device, wherein the terminal device comprises:
a current-voltage measuring unit configured to measure current and voltage as time-series from an electrical power line to which a plurality of electrical devices is connected;
a filtering unit configured to filter signal components of power frequency and harmonics thereof from the time-series of the measured current and voltage;
an admittance calculating unit configured to calculate admittance vector time-series from the filtered signal components;
an admittance transmitting unit configured to transmit the calculated admittance vector time-series to the server device; and
an estimated result receiving unit configured to receive an estimated result of the operational states of the plurality of electrical devices from the server device,
wherein the server device comprises:
an admittance receiving unit configured to receive the admittance vector time-series transmitted from the terminal device;
a feature vector retaining unit configured to retain feature vectors of the plurality of electrical devices;
a combination calculating unit configured to calculate combination patters of the retained feature vectors of the plurality of electrical devices;
a comparing unit configured to compare the combined feature vectors and the received admittance vector time-series to obtain the estimated result of the operational states of the plurality of electrical devices; and
an estimated result transmitting unit configured to transmit the obtained estimated result of the operational states of the plurality of electrical devices to the terminal device.
